(19) United States
(12) Patent Application Publication
(10) Pub. No.: US 2008/0141938 A1
(43) Pub. Date: Jun. 19, 2008

(54) Processing apparatus, coated article and method

(75) Inventors: Ramachandran Gopi Chandran, Bangalore (IN); George Theodore Dalakos, Niskayuna, NY (US); Dalong Zhong, Niskayuna, NY (US)

Correspondence Address: GENERAL ELECTRIC COMPANY;GLOBAL RESEARCH, PATENT DOCKET RM. BLDG. K1-4A59, NISKAYUNA, NY, 12309, US

(73) Assignee: General Electric Company, Schenectady, NY (US)

(21) Appl. No.: 11/638,039

(22) Filed: Dec. 13, 2006

(51) Int. Cl. C23C 16/00; B05D 7/00

(52) U.S. Cl. 118/723 E; 427/402

(57) ABSTRACT

A processing apparatus for use in a corrosive operating environment is provided. The apparatus includes a base substrate for placing a wafer thereon. The base substrate has a coefficient of thermal expansion. At least one electrode is embedded in or disposed on or under the base substrate. The electrode has a coefficient of thermal expansion in a range of from about 0.70 to about 1.25 times that of the base substrate coefficient of thermal expansion (CTE). At least one coating layer is disposed on the base substrate. The coating layer includes a composition capable of forming a calcium aluminate coating. The calcium aluminate coating layer is doped with one of MgO, CaO, CaF₂ and mixtures thereof to control the CTE of the coating layer to match the CTE of the base substrate. The apparatus is exposed to a corrosive operating environment at a temperature range of from about 25 degrees Celsius to about 1500 degrees Celsius. A coated article and associated method are provided.

### BACKGROUND

1. Technical Field

The invention includes embodiments that relate to an article or apparatus for use in the semiconductor processing industry and other corrosive environments, and methods for making articles and apparatuses thereof. In one embodiment, the invention also relates to methods of making or using compositions for use in coating articles and apparatuses for use in the semiconductor processing industry and other corrosive environments.

2. Discussion of Related Art

The process for fabrication of electronic devices comprises a number of process steps that rely on either the controlled deposition or growth of materials or the controlled and often selective modification of previously deposited/grown materials. Exemplary processes include Chemical Vapor Deposition (CVD), Thermal Chemical Vapor Deposition (TCVD), Plasma Enhanced Chemical Vapor Deposition (PECVD), High Density Plasma Chemical Vapor Deposition (HDP CVD), Expanding Thermal Plasma Chemical Vapor Deposition (ETP CVD), Metal Organic Chemical Vapor Deposition (MOCVD), etc. In some of the processes such as CVD, one or more gaseous reactants are used inside a reactor under low pressure and high temperature conditions to form a solid insulating or conducting layer on the surface of a semiconductor wafer, which is located on a substrate (wafer) holder placed in a reactor.

The substrate holder in the CVD process could function as a heater, which typically contains at least one heating element to heat the wafer; or could function as an electrostatic chuck (ESC), which comprises at least one electrode for electro-statically clamping the wafer; or could be a heater/ESC combination, which has electrodes for both heating and clamping. A substrate holder assembly may include a susceptor for supporting a wafer, and a plurality of heaters disposed under the susceptor to heat the wafer. The semiconductor wafer is heated within a confined environment in a processing vessel at relatively high temperature and often in an atmosphere that is highly corrosive.

After a deposition of a film of predetermined thickness on the semiconductor wafer, there often is spurious deposition on other exposed surfaces inside the reactor. This spurious deposition could present problems in subsequent depositions. It is therefore periodically removed with a cleaning process, i.e. in some cases after every wafer and in other cases after a batch of wafers has been processed. Common cleaning processes in the art include atomic fluorine based cleaning, fluorocarbon plasma cleaning, sulfur hexafluoride plasma cleaning, nitrogen trifluoride plasma cleaning, and chlorine trifluoride cleaning. In the cleaning process, the reactor components, e.g., walls, windows, the substrate holder and assembly, etc., are often corroded/chemically attacked. The corrosion can be extremely aggressive on surfaces that are heated to elevated temperatures, e.g. such as the operating temperature of a heater which may be in the 400 degrees Celsius to 500 degrees Celsius range, but can be as high as the 600 degrees Celsius to 1000 degrees Celsius range.

There is still a need for articles and apparatuses suitable for semiconductor-processing environments, including those employing corrosive gases, as currently employed materials for use in articles and components such as heaters and electrostatic chucks may be lacking in one or more desired properties or characteristics.

### BRIEF DESCRIPTION

A processing apparatus for use in a semiconductor processing chamber is provided in one embodiment according to the invention. The multi-layered apparatus includes a base substrate for placing a wafer thereon. The base substrate has a coefficient of thermal expansion (CTE). At least one electrode is embedded in or disposed on or under the base substrate. The electrode is selected from a resistive heating electrode, a plasma-generating electrode, an electrostatic chuck electrode, and an electron-beam electrode. The electrode has a coefficient of thermal expansion in a range of from about 0.75 to about 1.25 times that of the base substrate coefficient of thermal expansion. At least one coating layer is disposed on the base substrate, and comprises calcium aluminate. The apparatus is exposed to a corrosive operating environment at a temperature range of from about 25 degrees Celsius to about 1500 degrees Celsius, and is selected from one of: an environment comprising halogen, a plasma etching environment, a reactive ion etching environment, a plasma cleaning environment, and a gas cleaning environment. In one embodiment, the calcium aluminate coating layer is doped with at least an oxide of an alkaline earth metal to adjust (“tune”) the coefficient of thermal expansion (CTE) of the coating layer to match the CTE of the adjacent multi-layered substrate. In one embodiment, the dopant is selected from the group of MgO, CaO and mixtures thereof. In yet another embodiment, the coating layer further comprises CaF₂ to further help in tuning the CTE of the resulting coating.

A method for producing a wafer processing apparatus is provided in another embodiment. The method includes providing a base substrate comprising at least one of a nitride, carbide, carbonitride or oxynitride of elements selected from a group consisting of B, Al, Si, Ga, refractory hard metals, transition metals, and combinations thereof. A film electrode is deposited onto the base substrate, and the film electrode has a coefficient of thermal expansion in a range of from about 0.75 to about 1.25 of the base substrate layer. The base substrate and the film electrode are coated with a coating layer having a coefficient of thermal expansion in a range of from about 0.75 to about 1.25 of the film electrode. The coating layer comprises calcium aluminate, and optionally an alkaline earth metal oxide.

An article is provided that includes a base substrate, an electrode and a coating layer. The base substrate has a surface and supports the electrode. The electrode is supported by the base substrate. The coating layer is disposed on the base substrate surface and has a coefficient of thermal expansion that is within about 10 percent of the base substrate coefficient of thermal expansion or the electrode coefficient of thermal expansion, and the coating layer includes both calcium aluminate and at least one alkaline earth metal oxide. The coating layer, when exposed to 18 weight percent feedstock gas at about 400 degrees Celsius comprising oxygen gas and at least one of carbon tetrachloride gas or nitrogen fluoride gas, has an etch rate of less than about 15 Angstroms per minute, and the coating layer has a density that is greater than about 90 percent of the theoretically maximum density for a calcium aluminate monolith.

### DETAILED DESCRIPTION

The invention includes embodiments that relate to articles and apparatuses for use in the semiconductor processing industry and other corrosive environments, and methods for making articles and apparatuses thereof. In one embodiment, the invention also relates to methods of making or using compositions for use in coating articles and apparatuses for use in the semiconductor processing industry and other corrosive environments.

Approximating language, as used herein throughout the specification and claims, may be applied to modify any quantitative representation that could permissibly vary without resulting in a change in the basic function to which it is related. Accordingly, a value modified by a term such as “about” is not to be limited to the precise value specified. In some instances, the approximating language may correspond to the precision of an instrument for measuring the value.

As used herein, “capable of resisting etching” means being highly resistance against corrosion by corrosive gases such as fluorine and chlorine gases, and high resistance against plasma, for an etch rate in NF₃ at 600° C. of less than 100 Angstroms per min (A/min). In one embodiment, “capable of resisting etching” also means an etch rate in NF₃ at 600° C. of less than 50 A/min. In yet another embodiment, “capable of resisting etching” further means having an etching resistance rate to 18 weight percent feedstock gas comprising oxygen gas and at least one of carbon tetrachloride gas or nitrogen fluoride gas is less than about 10 Angstroms per minute at about 600° C.

As used herein, having a closely matched coefficient of thermal expansion (CTE) means that the CTE of one layer, e.g., the coating layer, is between about 0.75 to about 1.25 of the CTE of an adjacent layer, e.g., that of the base substrate which in embodiment is a multi-layered structure. Also used herein, “tuning the CTE” means controlling the CTE such that the CTE matches the CTE of an adjacent layer (or layers).

The invention may include embodiments that relate to a composition for use in a coating, relate to a coating, and relate to a coated article, i.e., heaters and/or electrostatic chucks (ESCs) for use in a semi-conductor processing environment. The invention may include embodiments that relate to methods of making or using compositions in coatings, coatings, and coated articles. Particularly, embodiments of the invention may relate to a calcium aluminate-type composition, and other embodiments may relate to substrate coating with a calcium aluminate coating. The substrate may be, for example, an article used in semiconductor wafer processing, such as a heater or an electrostatic chuck. Other articles may be used as a crucible or as a boat in metal vapor deposition.

The refractory composition capable of forming the coating layer in one embodiment comprises CaAl₄O₇. In one embodiment, the refractory composition may consist essentially of CaAl₄O₇. In another embodiment, the refractory composition further includes an oxide of an alkaline earth metal. Suitable alkaline earth metal oxides may include MgO, CaO and mixtures of MgO and CaO. In other embodiments, other alkaline earth metal oxides may be used. CaF₂ may be used as an additive with, or apart from, CaO and may be helpful in tuning the thermal conductivity of the resulting coating. CaO forms a liquid or semi-solid during sintering. The CaF₂ may act as flux, if present, and further may help in tuning thermal conductivity of the resulting coating.

If present, the alkaline earth metal oxide is added in a sufficient amount to tune the CTE coating layer to match the CTE of the adjacent base substrate or multi-layered structure. Typically, the base substrate will be much thicker than the electrode layers and will dictate the overall CTE of the structure. In one embodiment, the alkaline earth metal oxide may be present in an amount that is greater than about 0.001 weight percent based on the total weight of the composition. In one embodiment, the-alkaline earth metal oxide may be present in an amount that is less than about 5 weight percent. In one embodiment, the alkaline earth metal oxide may be present in an amount that is in a range of from about 0.001 weight percent to about 0.01 weight percent, from about 0.01 weight percent to about 0.1 weight percent, from about 0.1 weight percent to about 1 weight percent, from about 1 weight percent to about 2 weight percent, from about 2 weight percent to about 3 weight percent, from about 3 weight percent to about 4 weight percent, or from about 4 weight percent to about 5 weight percent.

A plurality of particles may be dispersed within the calcium aluminate coating layer. The particles may be included during the formation of the coating layer. Suitable particles may include, for example, aluminum nitride or silicon carbide. The particles may have an average particle size that less than about 100 micrometers. In one embodiment, the particles may have an average particle size in a range of from about 100 micrometers to about 75 micrometers, from about 75 micrometers to about 50 micrometers, about 50 micrometers, from about 50 micrometers to about 25 micrometers, from about 25 micrometers to about 15 micrometers, from about 15 micrometers to about 10 micrometers, or from about 10 micrometers to about 5 micrometers. Alone, or in combination with micrometer-sized particles disclosed above, nano-scale particle may be included in the coating layer. The nano-scale, or sub-micron sized, particles may be present in an amount that packs into voids formed between micrometer-sized particles. If nano-scale particles are present, the particles may have an average particle size in a range of from about 1000 nanometers to about 750 nanometers, from about 750 nanometers to about 500 nanometers, from about 500 nanometers to about 250 nanometers, from about 250 nanometers to about 100 nanometers, from about 100 nanometers to about 75 nanometers, from about 75 nanometers to about 50 nanometers, or less than about 50 nanometers. While the nano-scale particles and the micro-scale particles may be of the same material, in one embodiment, the nano-scale particles and the micro-scale particles may be formed of differing materials relative to each other.

Selection of particulate inclusions, disclosed hereinabove, based on one or more of size, morphology, composition, method of inclusion, characteristics, or properties may allow control over macroscopic functionality of the coating layer. For example, inclusion of aluminum oxide nano-scale particulates may increase the wear resistance, the abrasion resistance, the thermal transfer ability, and other properties of the coating layer in a manner attributable to the concentration by weight percent of the particles in the coating layer.

The fabrication of a thin outer coating layer may be achieved by drawing one or more continuous length of green sheet through a sintering furnace, and applying the green sheet to the substrate surface. A suitable sheet sintering method may include firing discrete green sheet while the sheet contacts the substrate surface. Coating defects analogous to sheet curling or sheet texturing may be reduced or eliminated by controlling -the amount, timing and/or duration of non-uniform static or dynamic frictional forces arising between the sheet and the substrate surface during formation. In one embodiment, a press may apply pressure to the sheet to reduce movement.

The green sheet may be pre-sintered. Pre-sintering the sheet may provide control over the phase assemblage and grain size of the polycrystalline ceramic coating layer. Crystal grain size in the final coating may affect properties and characteristics of the coating layer, such properties and characteristics may include the oxygen ion conductivity of the coating layer.

The green sheet may be reshaped, for example, by plastic or superplastic deformation, at or near the sintering temperatures of the ceramic, to provide a determined shape. Such determined shapes may include corrugated or other curved layers.

The heat bonding characteristics of a pre-sintered green sheet may allow multiple sheets or sheet stacks to permanently bond to themselves and to other ceramic, cermet and metallic material surfaces. A suitable bond may be formed without the use of supplemental sealing materials. In one embodiment, a suitable bond may be formed by low-pressure lamination at or near a sintering temperature of the green sheet material. A gas-tight seal between mating surfaces may be provided.

In addition to forming the coating by contacting a green sheet to the substrate surface and heat bonding thereto, other application methods suitable to form the coating layer may be used. Such suitable methods may include one or more of plasma spraying, sol-gel forming, hot isostatic pressing, and the like.

Properties of Heaters/Chucks Having Calcium Aluminate coatings: In one embodiment, the coating layer may be a calcium aluminate that can be coated or deposited onto a surface of the heater/ESC substrate, and may have one or more controllable property or characteristic. The property or characteristic may be affected by the selection of coating layer composition materials. In one embodiment, the electrical resistivity may be affected by selection of dopant(s) and the selection of the doping amounts. The coating layer may have an electrical resistivity of greater than about 10¹² Ohm meter. In one embodiment, the electrical resistivity may be in a range of from about 10¹² Ohm meter to about 10¹³ Ohm meter, from about 10¹³ Ohm meter to about 10¹⁴ Ohm meter, from about 10¹⁴ Ohm meter to about 10¹⁵ Ohm meter, from about 10¹⁵ Ohm meter to about 10¹⁶ Ohm meter, from about 10¹⁶ Ohm meter to about 10¹⁷ Ohm meter, from about 10¹⁷ Ohm meter to about 10¹⁸ Ohm meter, or greater than about 10¹⁸ Ohm meter. By selection of the substituting ion and/or dopants, the coating layer may be affected to be semi-conductive or even conductive. For example, the coating layer may have an electrical resistivity of less than about 10¹² Ohm meter. In one embodiment, the electrical resistivity may be in a range of from about 10¹² Ohm meter to about 10¹⁰ Ohm meter, from about 10¹⁰ Ohm meter to about 10⁸ Ohm meter, from about 10⁸ Ohm meter to about 10⁶ Ohm meter, from about 10⁶ Ohm meter to about 10⁴ Ohm meter, from about 10⁴ Ohm meter to about 10² Ohm meter, or less than about 100 Ohm meter. Electrical resistivity is a measure indicating how strongly a material opposes the flow of electric current. The electrical resistivity values may be unit measurements at process conditions to account for temperature dependence.

Dielectric constant or permittivity is a measure of the ability of the coating to resist the formation of an electric field within the coating layer. By selecting the composition for forming the coating layer, the dielectric constant of the coating layer may be affected. The coating layer may have a dielectric constant in a range of greater than about 5. In one embodiment, the coating layer may have a dielectric constant in a range from about 5 to about 6, from about 6 to about 7, from about 7 to about 8, or greater than about 8. The dielectric constant may be measured with reference to frequency. Depending on the composition selection the frequency may be greater than about 1000 kiloHertz. In one embodiment, the frequency may be in a range of from about 1000 kiloHertz to about 10 megaHertz, from about 10 megaHertz to about 100 megaHertz, from about 100 megaHertz to about 1 gigaHertz, from about 1 gigaHertz to about 2 gigaHertz, from about 2 gigaHertz to about 3 gigaHertz, or greater than about 3 gigaHertz.

By controlling the composition selection of the coating layer and/or the deposition or coating method, and/or firing time and temperature the porosity of the coating may be affected. The porosity of the coating layer may be less than 15 volume percent. In one embodiment, the coating layer porosity may be in a range of from about 15 volume percent to about 10 volume percent, from about 10 volume percent to about 5 volume percent, from about 5 volume percent to about 2.5 volume percent, or less than about 2 volume percent. The pores, if present, may be non-connecting so that even if voids or pores are present, the surface integrity or continuity of the coating layer is not breached or compromised.

By controlling the composition selection of the coating layer and/or the deposition or coating method, and/or firing time and temperature the thermal diffusivity of the coating may be affected. The thermal diffusivity of the coating layer may be in a range of greater than about 6×10⁻⁷ m²/sec. In one embodiment, the thermal diffusivity of the coating layer may be in a range of from about 6×10⁻⁷ m²/sec to about 1×10⁻⁶ m²/sec, from about 1×10⁻⁶ m²/sec to about 1×10⁻⁵ m²/sec, from about 1×10⁻⁵ m²/sec to about 1×10⁻⁴ m²/sec, from about 1×10⁻⁴ m²/sec to about 1×10⁻³ m²/sec, or greater than about 1×10⁻³ m²/sec.

By controlling the composition selection of the coating layer and/or the deposition or coating method, and/or firing time and temperature the thermal conductivity of the coating may be affected. The thermal conductivity of the coating layer may be in a range of from about 0.01 W/m-K to about 0.1 W/m-K, from about 0.1 W/m-K to about 1 W/m-K, from about 1 W/m-K to about 1.1 W/m-K, or greater than about 1.1 W/m-K.

By controlling the composition selection of the coating layer, for example doping with alkaline earth metal oxides such as MgO, CaO and mixtures of MgO and CaO, and/or the deposition or coating method, and/or firing time and temperature, the coefficient of thermal expansion (CTE) of the coating may be controlled. In one embodiment, the coefficient of thermal expansion may be in any of the following ranges: from about 0.1 to about 0.5, from about 0.5 to about 1, from about 1 to about 1.5, from about 1.5 to about 2, from about 2 to about 2.2, from about 2.2 to about 2.3, about 2.3, from about 2.3 to about 2.4, from about 2.4 to about 2.5, or greater than about 2.5. By another measure, the coating layer may have a coefficient of thermal expansion matched to the substrate, or to the undercoating layer on a coated substrate, by a determined percent difference. The determined percent difference may be less than about 10 percent. In one embodiment, the determined percent difference may be in a range of from about 10 percent to about 5 percent, from about 5 percent to about 2.5 percent, from about 2.5 percent to about 1 percent, from about 1 percent to about 0.5 percent, or less than about 0.5 percent difference in the coefficient of thermal expansion from coating layer to the substrate.

In one embodiment, the calcium aluminate coating layer may resist damaging effects in harsh environments. Particularly, the layer may resist etching when contacted to a halogen at a temperature in a range of greater than about 100 degrees Celsius. Halogens may include one or more of fluorine, chlorine, or bromine. In one embodiment, the environment may include an oxidant, such as oxygen. In one embodiment, the environment may include a solvent, such as carbon tetrachloride. The temperature may be in a range of from about 100 degrees Celsius to about 250 degrees Celsius, from about 250 degrees Celsius to about 500 degrees Celsius, from about 500 degrees Celsius to about 600 degrees Celsius, from about 600 degrees Celsius to about 700 degrees Celsius, from about 700 degrees Celsius to about 800 degrees Celsius, from about 800 degrees Celsius to about 900 degrees Celsius, from about 900 degrees Celsius to about 950 degrees Celsius, from about 950 degrees Celsius to about 1000 degrees Celsius, or greater than about 1000 degrees Celsius. The harsh environment may be acidic and may have an effective pH of less than about 6, in a range of from about 6 to about 4, from about 4 to about 2, or less than about 2. The environment may include plasma that may contain energized ions. Plasma environments may be relatively more likely to etch than other harsh environments, such as those environments containing halogens and oxidants at high temperatures. In the harsh environment, the etch resistance of the coating layer may be sufficient that the material loss of the coating layer is less than about 100 Angstroms per minute at a temperature of greater than about 400 degrees Celsius in the presence of a halogen and an oxidant. In one embodiment, the material loss rate may be less than about 50 Angstroms per minute, less than about 35 Angstroms per minute, or less than about 10 Angstroms per minute at about 400 degrees Celsius.

In the harsh environment, the coating layer may resist delamination, pitting, and cracking. Particularly, the coating layer may resist cracking due to thermal cycling of the substrate and/or thermal shock.

Heaters and Chucks Having Calcium Aluminate Coatings: As disclosed hereinabove, a heater/ESC comprising an embodiment of the invention may include the calcium aluminate coating layer disposed on a substrate. Suitable substrates for use with the coating layer may include one or more of fused silica or quartz (CTE=0.5), graphite, boron nitride, silicon carbide, and pyrolitic derivatives thereof. In one embodiment, the substrate comprises one of graphite; refractory metals, transition metals, rare earth metals and alloys thereof; a sintered material including at least one of oxide, nitride, carbide, carbonitride or oxynitride of elements selected from a group consisting of B, Al, Si, Ga, Y, refractory hard metals, transition metals; oxide, oxynitride of aluminum; and combinations thereof. In yet another embodiment, the base substrate comprises high thermal stability zirconium phosphate having a structure of NaZr₂ (PO₄)₃; refractory hard metals; transition metals; oxide, oxynitride of aluminum, and combinations thereof.

Pyrolitic graphite is a crystalline carbonaceous structure in which there is a relatively high degree of crystallite orientation relative to what may be found in common graphite materials. The pyrolitic graphite may exhibit anisotropic physical properties, and may be characterized by oriented slip planes.

The anisotropic properties may be measurable different in contrast to isotropic properties of common graphite. Pyrolitic graphite may be formed by chemical vapor decomposition of, for example, methane gas at relatively high temperature in a reactor chamber with a suitable inert diluent. The pyrolitic graphite may have a thermal conductivity in an orientable direction in a range, in plane, of about 500 watt/meter-K or greater. In one embodiment, the in-plane thermal conductivity may be in a range of from about 500 watt/meter-K to about 600 watt/meter-K, from about 600 watt/meter-K to about 700 watt/meter-K, or greater than about 700 watt/meter-K. Skew relative to the plane, and the thermal conductivity may be less than about, 10 watt/meter-K. In one embodiment, the out of plane thermal conductivity may be in a range of from about 10 watt/meter-K to about 7.5 watt/meter-K, from about 7.5 watt/meter-K to about 5 watt/meter-K, from about 5 watt/meter-K to about 3.5 watt/meter-K, or less than about 3.5 watt/meter-K.

Regardless of the substrate, by incorporated one or more determined dopants or one or more substituted ions, the emissivity of the coating layer may be controlled. The emissivity of commercially available pyrolitic boron nitride heating units may be about 0.55 at a wavelength of 1.55 micrometers wavelength. For purposes of comparison an ideal black body at the same wavelength would have a radiation thermal efficiency of 100% representing a measurement of 1.00. In one embodiment, the pyrolitic boron nitride coating may have an emissivity greater than about 0.55, in a range of from about 0.55 to about 0.65, from about 0.65 to about 0.7, from about 0.7 to about 0.75, from about 0.75 to about 0.8, from about 0.8 to about 0.85, or greater than about 0.85.

In particular, a pyrolitic boron nitride surface may support a coating layer having a coefficient of thermal expansion that is matched to a determined amount to the pyrolitic boron nitride. Determined amount of coefficient of thermal expansion match may be expressed as a percentage difference or as a ratio of coefficients of thermal expansion. With regard to percent difference, in this instance, the determined amount may be less than about 10 percent, in a range of from about 10 percent to about 5 percent, from about 5 percent to about 2 percent, from about 2 percent to about 1 percent, or less than 1 percent difference. With regard to ratio, the pyrolitic boron nitride may have a coefficient of thermal expansion of about 2.3, and the coating may have a coefficient of thermal expansion in a range of from about 2 to about 2.2, from about 2.2 to about 2.3, exactly 2.3, or from about 2.3 to about 2.4; so that the ratio may be about 1:1.

The thickness of the pyrolitic graphite, if an undercoating, may provide a determined amount of spatial separation between a graphite body and a pyrolitic boron nitride layer and may provide a controllable amount of thermal leveling. Prior to application of the calcium aluminate coating layer according to an embodiment of the invention, the substrate may be pre-coated. The pre-coated substrate may be referred to herein as the substrate or as the coated substrate and care should be taken that the coated substrate that is ready for coating with the coating layer is not confused with the finished article, which will have a coating layer disposed on the substrate surface, or on the surface of the pre-coat layer on the substrate. Particularly, the substrate may be a coated substrate, or may be a multi-layered article.

In one embodiment, the substrate is first coated with the calcium aluminate coating layer, then overcoated with another layer, e.g., a coating layer comprising at least one of an oxide, nitride, oxynitride, carbide, or nitride of one or more elements selected from a group consisting of Al, B, Si, Ga, Y, refractory hard metals, transition metals, and combinations thereof. In another embodiment, the calcium aluminate coating layer is applied after the substrate is first coated with undercoating layers.

A number of materials may be useful as substrate undercoating coating layers. Such materials may include metal carbide. Suitable metal carbides may include one or more of boron carbide, tantalum carbide, or silicon carbide. If present, the coating layer of the graphite body may include one or more of a nitride, carbide, carbonitride or oxynitride of elements B, Al, Si, Ga, as well as refractory hard metals, transition metals, and rare earth metals. Other suitable coating materials may include complexes and/or combinations of two or more thereof.

In one embodiment, the undercoating layer may include one or more of pyrolitic boron nitride, aluminum nitride (AIN), a complex of AIN and BN, pyrolitic boron nitride (PBN) and a carbon dopant, aluminum nitride including an amount of Y₂O₃. Because some of the substrate undercoating layers may be colored differently relative to the substrates, the coating layer integrity may be visually determinable.

Embodiments of heaters and ESCs may include multi-layer coating layers and/or gradient or graded concentration coating layers. For example, on a pyrolitic boron nitride substrate using a sodium zirconium phosphate coating layer the coating layer may a sub-layer adjacent to the pyrolitic boron nitride surface that may be about 90 wt. % pyrolitic boron nitride and about 10 wt. % of the sodium zirconium phosphate, while an outward-facing sub-layer may be less than 5 wt. % pyrolitic boron nitride and greater than 95 wt. % of the sodium zirconium phosphate. The concentration gradient may vary in a linear or a non-linear proportion across the thickness of the coating layer. Such a graded concentration may be obtained by introducing select ingredients into the reaction/deposition chamber during the formation of the coating layer for co-deposition.

Suitable methods for depositing a coating layer or layers onto the substrate may include physical vapor deposition (PVC), wherein the coating material, e.g. boron nitride and/or aluminum nitride transfers, in vacuum, into the gaseous phase through a purely physical method to deposit on the substrate surface. Sputtering can be used, wherein a solid target may be bombarded by atomized high-energy ion particles in vacuum or an inert gas environment. Another deposition method may include chemical vapor deposition (CVD). In contrast to the PVD method, the CVD method has one or more associated chemical reactions. The gaseous components produced at relatively elevated temperatures through thermal, plasma, photon or laser-activated chemical vapor deposition may transfer with an inert carrier gas, e.g. argon into a reaction chamber in which the chemical reaction takes place.

Pyrolitic boron nitride (PBN) may be formed by chemical vapor deposition of boron nitride in a reactor chamber by the vapor phase reaction of ammonia and a boron containing gas such as boron trichloride (BCl₃). The pyrolitic boron nitride may be relatively pure. In one embodiment, the pyrolitic boron nitride may be doped with a thermally conductive material, an electrically conductive material, or a material that is both thermally conductive and electrically conductive. A suitable conductive material may be carbon. The carbon, as a dopant, may be present in an amount in an amount of less than about 5 weight percent of pyrolitic boron nitride composition. In one embodiment, the carbon may be present in an amount in a range of from about 5 weight percent to about 4 weight percent, from about 4 weight percent to about 3 weight percent, from about 3 weight percent to about 2 weight percent, from about 2 weight percent to about 1 weight percent, from about 1 weight percent to about 0.5 weight percent, or less than about 0.5 weight percent. The doped pyrolitic boron nitride coating may be formed by the codeposition of pyrolitic boron nitride and pyrolitic graphite (PG). The codeposition may be performed by introducing a hydrocarbon gas such as, for example, methane into the reactor furnace during the deposition of pyrolytic boron nitride. Codepositing pyrolitic boron nitride with pyrolitic graphite (PG) may deposit the components at about the same rate as each other, but the carbon codeposition may be less, by a factor of about greater than or equal to 20, relative to a pure deposit because ammonia may remove deposited carbon as HCN.

A pyrolitic boron nitride heating unit may include a dielectric base (e.g., boron nitride) and a heating element formed from a conductive material capable of electrically resistive heating (the components collectively “heater”). The conductive material may include graphite, and which may include pyrolitic graphite. The heating element may connect to an external power supply or may be capable or susceptible to heating as a response to radiation energy input.

In one embodiment, a freestanding pyrolitic boron nitride structure may be formed by the thermal decomposition of boron trichloride and ammonia vapors at a reaction temperature in a range of from about 1450 degrees Celsius and 2300 degrees Celsius. The pyrolitic boron nitride substrate may be codeposited with silicon to achieve a low thermal expansion in close conformity to the thermal expansion of carbon or graphite material under controlled conditions of gas flow rate and deposition temperature. The codeposited coating may include a complex of PB(Si)N containing essentially no free silicon. To increase the silicon content in the coating composition to be in a range of from about 7 weight percent to about 35 weight percent, the deposition temperature may be controlled to be in a temperature range of from about 1300 degrees Celsius to about 1500 degrees Celsius, and the ammonia flow rate may be relative higher than the flow rate of boron and silicon.

In one embodiment, a suitable substrate, or undercoated substrate, may include silicon reacted with boron and nitride in a compositional relationship expressed as BSiₓN₁+1.33 x, with essentially no free silicon present. The content of silicon may be in a range of from about 2.0 weight percent Si to about 42 weight percent Si. With a silicon content of the substrate, or an undercoat on the substrate, of about 7.0 weight percent, the rate of oxidative weight loss of the coating, by itself, at about 1500 degrees Celsius is one-tenth that of a pure pyrolitic boron nitride substrate. Silicon content of above 35.0 weight percent may be undesirably brittle.

In one embodiment, the substrate may be a low-expansion, high-modulus carbon-carbon composite. The carbon-carbon composite may be a woven mat or fabric of carbon fibers with a carbonaceous material directly bonded to the carbon fibers to form a unitary structure. Other suitable carbon-carbon composites may include a non-woven fabric infused with a carbonaceous material bonded to the carbon fibers. An example of a carbon-carbon composite is a woven fabric of carbon fibers obtained by carbonizing polyacrylonitrile (PAN) fibers, forming a shaped substrate from the carbon fibers, and depositing a pyrolitic material such as pyrolitic carbon on the carbon fibers. The deposition of pyrolitic carbon may include introducing a hydrocarbon gas into the furnace containing the carbon fiber substrate under conditions permitting the gas to decompose and carbonize at the surface of the carbon fibers.

Carbon-carbon or graphite substrates can be mounted within the deposition chamber. For example, thin strips can be supported in V-shaped slots; plates can be supported on rods or slats; and the substrates may be suspended from screws or supported on the ends of sharpened rods.

In the growth of superconducting films, it may be sometimes useful to introduce oxygen into the atmosphere of the reacting chamber in which the superconducting film is grown. The oxygen in that atmosphere may react with the graphite conductor in the heating unit to oxidize the conductor causing an open circuit unless a precaution is taken. Because existing electrical contacts for pyrolitic boron nitride heating units may include a screw or clamp to for bias against the pyrolitic graphite conductor, the screw or clamp element may be exposed to the reactive atmosphere. This type of contact arrangement is not impermeable to a reactive gas and if the temperature at the point of contact with the graphite heating element may be sufficiently high (such as about 400 degrees Celsius) that oxidation occur without the precaution. Thermal stress may cause the screw or clamp to lose pressure at the point of contact. Loss of pressure may allow a gap and may cause arcing at the contact terminal. Arcing may damage the heating unit.

Applications for Substrates coated with calcium aluminate Coatings: Suitable end-use applications may include one or more articles used for semiconductor wafer processing in plasma environment. Such articles may include one or more of a heater, a chuck, a combined heater/chuck, and a susceptor. Other suitable end-use applications may include an article used for semiconductor wafer processing, flat panel display processing, photovoltaic device processing, and other flat panel electronic device processing applications.

Heaters with substrate coated with calcium aluminate coatings may also be useful in processing involving molecular beam epitaxy, low-gravity experimentation, electron microscopy, and in the growth of superconducting films. The substrate for calcium aluminate coating may also be a boat. Suitable boats may be useful for vacuum metal vapor deposition onto receiving substrates of metal, glass, or plastic. Suitable metals for deposition may include one or more of aluminum, copper, tin, or zinc. Resistance heated vaporization boats may include one or more intermetallic composite materials. Suitable intermetallic composite materials may include one or more of titanium diboride and boron nitride; titanium diboride and aluminum nitride; boron nitride and aluminum nitride; or titanium diboride, boron nitride and aluminum nitride. The vaporization boat may include a layer of pyrolytic boron nitride overcoated by the composite material. Fabrication of a suitable boat may include producing a rectangular substrate of graphite, which is then coated with the pyrolytic boron nitride. The opposite ends of the substrate may remain exposed to permit the boat to be electrically connected in circuit with a power supply via a contact assembly or clamp.

In one embodiment, the article is used as an electrostatic chuck for use in wafer processing. An electrostatic chuck may be a clamping device. The chuck may hold a semiconductor wafer in a clamped, fixed position during semiconductor wafer manufacture. A clamping force may be created by generating an electrostatic field around the chuck. The field may impart an electrical charge upon a conductor proximate to the wafer. A dielectric material may separate the conductor from the wafer, with the wafer disposed between a power source and the conductor in a monopolar configuration in which the wafer serves also as an electrode. Alternatively, the configuration may be a dipolar configuration. In either configuration, the insulating dielectric layer may separate the charged electrode(s). To reduce or eliminate the tendency to crack between, for example, the conductor and the insulator the thermal expansion coefficient differential may be reduced or eliminated. The electrostatic attraction force or “chuck clamping force” may be increased by limiting the resistivity of the insulator to a value smaller than 10¹⁴ Ohms-cm. Stated otherwise, a large supplementary clamping force may be generated if a current of very low magnitude is permitted to pass through the insulative separator. This is known as the “Johnsen-Rahbek” effect. The electrical resistivity of the coating, functioning as an insulating layer, may be of a value smaller than 10¹⁴ Ohms-cm. In one embodiment, the resistivity may be in a range of from about 10¹⁴ Ohms-cm to about 10¹³ Ohms-cm, from about 10¹³ Ohms-cm to about 10¹² Ohms-cm, from about 10¹² Ohms-cm to about 10¹¹ Ohms-cm, from about 10¹¹ Ohms-cm to about 10¹⁰ Ohms-cm, from about 10¹⁰ Ohms-cm to about 10⁹ Ohms-cm, from about 10⁹ Ohms-cm to about 10⁸ Ohms-cm, or less than about 10⁸ Ohms-cm. The charge dissipation time for the wafer may be less than about 2 seconds, in a range of from about 2 seconds to about 1 second, from about 1 second to about 0.5 seconds, or may be less than about 0.5 seconds.

With regard to the structure of an article comprising an embodiment of the invention, a plurality of configurations may be selected based on the end-use application. In one embodiment, the article may be arranged to have a graphite/pyrolitic boron nitride basecoat/pyrolitic graphic electrode/pyrolitic boron nitride overcoat/calcium aluminate etch resistant layer. In another embodiment, the configuration may be graphite/pyrolitic boron nitride basecoat/pyrolitic graphic electrode/calcium aluminate etch resistant overcoat layer. In another embodiment, the configuration may be pyrolitic boron nitride substrate/pyrolitic graphic electrode/pyrolitic boron nitride overcoat/calcium aluminate etch resistant layer. In yet another embodiment, the configuration may be pyrolitic boron nitride substrate/pyrolitic graphic electrode/calcium aluminate etch resistant overcoat layer. In another embodiment, the configuration may be a hot pressed boron nitride substrate/pyrolitic graphic electrode/pyrolitic boron nitride overcoat/calcium aluminate etch resistant layer. In yet another embodiment, the configuration may be a hot pressed boron nitride substrate/pyrolitic graphic electrode/ calcium aluminate etch resistant overcoat layer. In another embodiment, the configuration may be another insulating substrate/pyrolitic graphic electrode/PBN pyrolitic graphic overcoat/calcium aluminate etch resistant layer; or the configuration may be another insulating substrate/PG electrode/calcium aluminate etch resistant overcoat layer; where “another insulating substrate” may include one or more oxides, nitrides, oxynitride, carbides, and mixtures of two or more thereof.

In a particular embodiment, the configuration may include a conductive or an insulating substrate with at least one undercoating layer, and which may include at least one electrode layer overcoated with an calcium aluminate etch resistant material. In another embodiment, a bulk calcium aluminate heater with embedded electrodes inside may be formed. In one embodiment, the electrodes have a CTE that closely matches the CTE of the adjacent substrate that it is disposed on, as well as the CTE of the protective coating layer. In one embodiment, the electrodes have a CTE ranging from 2.0×10⁻⁶/K to 10×10⁻⁶/K in a temperature range of 25° C. to 1000° C. In yet another embodiment, the electrodes are film electrodes with a CTE that is between about 0.70 to about 1.25 of the CTE of the adjacent layer.

For substrates distinct from the end-use application, a coating layer according to an embodiment of the invention could be used with a substrate comprising one or more of Si, GaAs, AlN, GaN, glass, or another substrate.

An article 100 comprising an embodiment of the invention is shown in FIG. 1. The article 100 includes a substrate 102 and a coating layer 104 disposed on an outward facing surface of the substrate 102. In the illustrated embodiment, the substrate is a pyrolitic boron nitride heater for use in a wafer processing device. The coating is a calcium aluminate coating.

### EXAMPLES

The following illustrate methods and embodiments in accordance with the invention, and as such should not be construed as imposing limitations upon the claims. Unless specified otherwise, all ingredients are commercially available from such common chemical suppliers as Alpha Aesar, Inc. (Ward Hill, Mass.), Spectrum Chemical Mfg. Corp. (Gardena, Calif.), and the like.

### Example 1

### Eight Samples are Prepared having a Base of Calcium Aluminate, and Calcium Aluminate with Additions of Alkaline Earth Metal Oxides

During formation, the resulting penetration of the CA₂ matrix by a MgO-bearing high temperature forms a liquid at the interface around a periclase grain. Formation includes firing each of the samples at a temperature of up to 1650 degrees Celsius for half an hour. Some samples contain additions of MgO and CaO (admixed in the form of a metal carbonate). The calcium dialuminate is synthesized by mixing chemically pure reagents, pre-firing, regrinding and final firing at 1450 degrees Celsius for five hours. The powders thus obtained were ground and premixed along with additives for 4 hours on a rack mill using PSZ grinding media. This premixed powder, containing the additives, is compacted under uniaxial 40 MPa pressure into cylindrical specimens of 7 mm diameter and 20 mm height. These green specimens are then fired to maximum temperature 1650 degrees Celsius for ½ hour to form samples. The samples are tested. Tables 1-2 list coefficient of thermal expansion data for the samples:

Examples of chemicals and amounts used for synthesis of CaAl₄O₇ with MgO & CaCO₃ additives are given below in Tables 3-4. The materials are mixed on a rack mill using 125 ml Nalgene bottles containing 5 nos of ½″ and 20 nos of ¾″ cylindrical YPSZ grinding media for 6 hours. The powders are calcined at 1450° C., 5 hours in air. The resulting powders are mixed with in a Nalgene bottle containing 7 nos of ½″ and 25 nos of ¾″ cylindrical YPSZ grinding media for 6 hours. The powders are removed, compacted, and sintered at 1650° C. for 30 minutes in air to obtain a dense body of the aluminate.

The materials are mixed on a rack mill using 125 ml Nalgene bottles containing 5 nos of ½″ and 20 nos of ¾″ cylindrical YPSZ grinding media for 6 hours. The powders are calcined at 1450° C. for 5 hours in air. The resulting powders are mixed for 6 hours in a Nalgene bottle containing 7 nos of ½″ and 25 nos of ¾″ cylindrical YPSZ grinding media with 4.5 wt % of CaCO₃ (0.18 grams for 4 grams of CaAl₄O₇), 3.5 wt % MgO (0.14 grams for 4 grams of CaAl₄O₇). Then the powders are removed, compacted, and sintered at 1650° C. for 30 minutes in air to obtain a dense body of aluminate containing the MgO additive.

TABLE 1
Thermal expansion data for calcium dialuminate specimens containing MgO additions.

| Percent weight | Mean linear thermal expansion coefficient ( α̅ × 10⁶° C.⁻¹) | | | | | | | | |
|---|---|---|---|---|---|---|---|---|---|
| addition of | from 20° up to temperature (° C.) | | | | | | | | |
| MgO (above 100% CA₂) | 100 | 200 | 300 | 400 | 500 | 600 | 700 | 800 | 900 |
| 0 | 2.3 | 3.1 | 3.5 | 3.8 | 4.0 | 4.1 | 4.2 | 4.3 | 4.5 |
| 1 | 2.8 | 3.5 | 3.9 | 4.1 | 4.2 | 4.3 | 4.4 | 4.6 | 4.7 |
| 2 | −0.1 | 0.8 | 1.2 | 1.5 | 1.8 | 2.1 | 2.4 | 2.7 | 2.9 |
| 3 | −0.3 | 0.1 | 0.4 | 0.8 | 1.2 | 1.5 | 1.9 | 2.3 | 2.6 |
| 4 | −0.2 | 0.0 | 0.5 | 0.8 | 1.3 | 1.6 | 2.0 | 2.4 | 2.6 |
| 5 | 0.4 | 0.6 | 0.9 | 1.2 | 1.6 | 1.8 | 2.2 | 2.5 | 2.9 |

TABLE 2
Thermal expansion data for calcium dialuminate specimens containing CaO additions
(introduced as CaCO₃)

| Percent weight | Mean linear thermal expansion coefficient ( α̅ × 10⁶° C.⁻¹) | | | | | | | | |
|---|---|---|---|---|---|---|---|---|---|
| addition of | from 20° up to temperature (° C.) | | | | | | | | |
| CaO (above 100% CA₂) | 100 | 200 | 300 | 400 | 500 | 600 | 700 | 800 | 900 |
| ~2.2 (4% CaCO₃) | −0.1 | 0.1 | 0.3 | 0.5 | 0.6 | 1.0 | 1.4 | 1.8 | 2.2 |
| ~2.8 (5% CaCO₃) | −0.5 | 0.1 | 0.4 | 0.7 | 1.2 | 1.5 | 1.9 | 2.3 | 2.6 |
| ~3.4 (6% CaCO₃) | 0.0 | 0.5 | 0.8 | 1.1 | 1.4 | 1.7 | 2.2 | 2.5 | 2.9 |

Specifically, Table 3 lists the amount of alkaline earth metal oxide present, if any. Table 4 lists Etch Rate data in a harsh environment.

TABLE 3
Sample number vs. amount of additive.

| | | Amount in |
|---|---|---|
| Sample | Additive | weight percent |
| 1 | MgO | 0 |
| 2 | MgO | 1 |
| 3 | MgO | 2 |
| 4 | MgO | 3.5 |
| 5 | MgO | 5 |
| 6 | CaCO3 | 4.5 |
| 7 | CaCO3 | 5 |
| 8 | CaCO3 | 6 |

TABLE 4
Etch rate data

| | Density | Wt (g), | Wt (g), | Area, | Etch Rate |
|---|---|---|---|---|---|
| Sample | g/cm³ | initial | final | cm² | (A/min) |
| 4 | 3.117657 | 3.917772 | 3.917849 | 5.780538 | −3.56052 |
| 6 | 3.069885 | 3.85774 | 3.857447 | 5.300000 | 15.00681 |

Reference is made to substances, components, or ingredients in existence at the time just before first contacted, formed in situ, blended, or mixed with one or more other substances, components, or ingredients in accordance with the present disclosure. A substance, component or ingredient identified as a reaction product, resulting mixture, or the like may gain an identity, property, or character through a chemical reaction or transformation during the course of contacting, in situ formation, blending, or mixing operation if conducted in accordance with this disclosure with the application of common sense and the ordinary skill of one in the relevant art (e.g., chemist). The transformation of chemical reactants or starting materials to chemical products or final materials is a continually evolving process, independent of the speed at which it occurs. Accordingly, as such a transformative process is in progress there may be a mix of starting and final materials, as well as intermediate species that may be, depending on their kinetic lifetime, easy or difficult to detect with current analytical techniques known to those of ordinary skill in the art.

Reactants and components referred to by chemical name or formula in the specification or claims hereof, whether referred to in the singular or plural, may be identified as they exist prior to coming into contact with another substance referred to by chemical name or chemical type (e.g., another reactant or a solvent). Preliminary and/or transitional chemical changes, transformations, or reactions, if any, that take place in the resulting mixture, solution, or reaction medium may be identified as intermediate species, master batches, and the like, and may have utility distinct from the utility of the reaction product or final material. Other subsequent changes, transformations, or reactions may result from bringing the specified reactants and/or components together under the conditions called for pursuant to this disclosure. In these other subsequent changes, transformations, or reactions the reactants, ingredients, or the components to be brought together may identify or indicate the reaction product or final material.

Throughout the specification and appended claims, range limitations may be combined and/or interchanged. Such ranges are identified and include all the logical sub-ranges contained therein unless context or language indicates otherwise. The embodiments described herein are examples of compositions, structures, systems, and methods having elements corresponding to the elements of the invention recited in the claims. This written description may enable those of ordinary skill in the art to make and use embodiments having alternative elements that likewise correspond to the elements of the invention recited in the claims.

1. A processing apparatus for use in a semiconductor processing chamber, the apparatus comprising:
an underlying structure comprising a base substrate for placing a wafer thereon, the base substrate has a coefficient of thermal expansion (CTE);
at least one electrode embedded in or disposed on or under the base-substrate, selected from a resistive heating electrode, a plasma-generating electrode, an electrostatic chuck electrode, and an electron-beam electrode; and
at least a coating layer disposed on the base substrate of the underlying structure, the coating layer comprising a calcium aluminate having the formula CaAl₄O₇,
wherein the apparatus is exposed during use to a corrosive operating environment at a temperature range of about 25° C. to 1500° C. selected from one of: an environment comprising halogen, a plasma etching environment, a reactive ion etching environment, a plasma cleaning environment, and a gas cleaning environment.

2. The processing apparatus as defined in claim 1, wherein the calcium aluminate coating layer further comprises a sufficient amount of an alkaline earth metal oxide for the coating layer to have a coefficient of thermal expansion that matches the coefficient of thermal expansion of the underlying structure.

3. The processing apparatus as defined in claim 2, wherein the alkaline earth metal oxide comprises CaO, CaF₂ or both CaO and CaF₂.

4. The processing apparatus as defined in claim 2, wherein the alkaline earth metal oxide comprises MgO.

5. The processing apparatus as defined in claim 2, wherein the alkaline earth metal oxide is present in the calcium aluminate coating in an amount greater than about 0.001 weight percent based on the total weight of the calcium aluminate coating.

6. The processing apparatus as defined in claim 2, wherein the alkaline earth metal oxide is present in the calcium aluminate coating in an amount less than about 5 weight percent based on the total weight of the calcium aluminate coating.

7. The processing apparatus as defined in claim 2, wherein the alkaline earth metal oxide is present in the calcium aluminate coating in an amount in a range of from about 1 weight percent to about 3 weight percent based on the total weight of the calcium aluminate coating layer.

8. The processing apparatus as defined in claim 2, wherein the alkaline earth metal oxide is present in the calcium aluminate coating in an amount in a range of from about 3 weight percent to about 8 weight percent based on the total weight of the calcium aluminate coating.

9. The processing apparatus as defined in claim 2, wherein the alkaline earth metal oxide is present and comprises both MgO and CaO.

10. The processing apparatus as defined in claim 9, wherein the MgO and CaO are present in a ratio in a range of from about 0.001:1 to about 1:1.

11. The processing apparatus as defined in claim 9, wherein the MgO and CaO are present in a ratio of in a range of from about 1:1 to about 1:0.001.

12. The processing apparatus as defined in claim 9, wherein the calcium aluminate coating layer further comprises CaF₂.

13. The processing apparatus as defined in claim 1, wherein the calcium aluminate coating layer further comprises a plurality of particles dispersed therein.

14. The processing apparatus as defined in claim 13, wherein the particles comprise aluminum nitride, silicon carbide, or both aluminum nitride and silicon carbide.

15. The processing apparatus as defined in claim 13, wherein the particles have an average particle size that less than about 50 micrometers.

16. The processing apparatus as defined in claim 1, wherein the calcium aluminate coating layer has a coefficient of thermal expansion in a range of from about 2.2 to about 2.4.

17. The processing apparatus as defined in claim 1, wherein the calcium aluminate coating layer has a coefficient of thermal expansion in a range of from about −0.1 to about 4.7.

18. The processing apparatus as defined in claim 1, wherein the calcium aluminate coating layer has a coefficient of thermal expansion of greater than 4.4.

19. The processing apparatus as defined in claim 1, wherein the calcium aluminate coating layer has a CTE that is within about 10 percent of the coefficient of thermal expansion of the substrate.

20. The processing apparatus as defined in claim 1, wherein the calcium aluminate coating layer has an etch rate of less than 100 Angstroms per min when exposed to the corrosive operating environment at a temperature in a range of greater than about 100 degrees Celsius.

21. The processing apparatus as defined in claim 20, wherein the calcium aluminate coating layer has an etch rate of less than 50 Angstroms per min when exposed to the corrosive operating harsh environment at a temperature in a range of greater than about 100 degrees Celsius.

22. The processing apparatus as defined in claim 21, wherein the coating layer has an etch rate of less than 50 Angstroms per min when exposed to the corrosive operating environment at a temperature in a range of greater than about 400 degrees Celsius.

23. The processing apparatus as defined in claim 1, wherein the coating layer, when exposed to 18 weight percent feedstock gas at about 400 degrees Celsius comprising oxygen gas and at least one of carbon tetrachloride gas or nitrogen fluoride gas, has an etch rate of less than about 15 Angstroms per minute.

24. The processing apparatus as defined in claim 1, wherein the base substrate comprises an electrically insulating material selected from the group of oxides, nitrides, carbides, carbonitrides or oxynitrides of elements selected from a group consisting of B, Al, Si, Ga, Y; refractory hard metals; transition metals; oxide or oxynitride of aluminum, and combinations of two or more thereof.

25. The processing apparatus as defined in claim 1, wherein the base substrate comprises an electrically conducting material selected from the group of graphite, refractory metals, transition metals, rare earth metals and alloys thereof.

26. The processing apparatus as defined in claim 1, wherein the calcium aluminate coating layer has a density that is greater than about 90 percent of the theoretically maximum density for a calcium aluminate monolith.

27. The processing apparatus of claim 1, wherein the calcium aluminate coating layer has a porosity of less than about 5 volume percent.

28. The processing apparatus of claim 1, wherein the calcium aluminate coating layer has a thermal diffusivity greater than about 6×10⁻⁷ m²/sec.

29. A method for producing a wafer processing apparatus, comprising:
providing a base substrate comprising at least one of a nitride, carbide, carbonitride or oxynitride of elements selected from a group consisting of B, Al, Si, Ga, refractory hard metals, transition metals, and combinations thereof;
depositing a film electrode onto the base substrate, the film electrode has a coefficient of thermal expansion in a range of from about 0.75 to about 1.25 of the base substrate layer; and
coating the base substrate and the film electrode with a coating layer having a coefficient of thermal expansion in a range of from about 0.75 to about 1.25 of the base substrate,
wherein the coating layer comprises calcium aluminate, and optionally an alkaline earth metal oxide.

30. An article, comprising:
a base substrate having a surface and configured to support an electrode;
at least one electrode supported by the base substrate; and
a coating layer disposed on the base substrate surface and having a coefficient of thermal expansion that is within about 10 percent of the base substrate coefficient of thermal expansion or the electrode coefficient of thermal expansion, and
the coating layer comprising calcium aluminate and at least one alkaline earth metal oxide, and
the coating layer, when exposed to 18 weight percent feedstock gas comprising oxygen gas and at least one of carbon tetrachloride gas or nitrogen fluoride gas at about 400 degrees Celsius, has an etch rate of less than about 15 Angstroms per minute, and
the coating layer has a density that is greater than about 90 percent of the theoretically maximum density for a calcium aluminate monolith.
